(19) United States
(12) Patent Application Publication
(10) Pub. No.: US 2010/0045873 A1
(43) Pub. Date: Feb. 25, 2010

(54) VSB DEMODULATING APPARATUS AND TELEVISION RECEIVER

(75) Inventor: Haruka Takano, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/531,166

(22) PCT Filed: Sep. 25, 2008
(86) PCT No.: PCT/JP2008/002666

§ 371 Date: Sep. 14, 2009

(30) Foreign Application Priority Data
Sep. 26, 2007 (JP) 2007-248806

(51) Int. Cl. H04N 5/455; H03D 1/24

(52) U.S. Cl. 348/726; 375/321; 348/E05.097

(57) ABSTRACT

A VSB modulated signal is properly demodulated even when there is phase error variation in the VSB modulated signal. A VSB demodulator configured to demodulate a VSB modulated signal including a plurality of segments each having a predetermined segment synchronization component includes: a channel estimation section configured to generate a timing signal synchronous with the segment synchronization components; a phase variation detection section configured to detect a phase error in the VSB modulated signal in accordance with timing indicated by the timing signal, and output a detection signal corresponding to variation in the detected phase error; and a waveform equalization section, including a filter, configured to update a coefficient of the filter and perform waveform equalization on the VSB modulated signal. The waveform equalization section increases a coefficient update gain for the filter when the detection signal indicates that the variation in the phase error is larger than a predetermined value.

### TECHNICAL FIELD

The present invention relates to a vestigial sideband (VSB) demodulator, and more particularly relates to a technique for reducing effects of phase variation in a VSB modulated signal.

### BACKGROUND ART

It is generally known that a VSB demodulator is subjected to adverse effects, such as an increase in the required C/N ratio (Carrier to Noise Ratio), when the phase of a main signal of a received VSB modulated signal or the phase of a delayed signal thereof, which is delayed from the main signal, varies.

FIG. 1 illustrates the configuration of a data frame defined by the Advanced Television Systems Committee (ATSC) adopted in North America, etc. As shown in FIG. 1, each data frame consists of two data fields, each containing 313 data segments. Each data segment includes 832 symbols. The first four symbols in each data segment are defined as a segment synchronization component.

Patent document 1 discloses a technique for performing feedback control using existing values defined in the frame configuration of FIG. 1 in such a manner that the sum total of in-phase components of the four symbols in a segment synchronization component is 0, thereby canceling a phase error and low-speed phase error variation in a main signal.
Patent Document 1: Japanese Laid-Open Publication No. 2001-168931

### DISCLOSURE OF THE INVENTION

### Problem that the Invention Intends to Solve

However, the four symbols serving as the segment synchronization component are greatly affected by symbols located before and after those four symbols, causing phase error information to contain much noise. Due to this, in the technique disclosed in Patent Document 1, convergence time in calculating a phase error is long, and the phase error cannot be detected accurately.

Now, a description will be made of the effects on the segment synchronization component caused by the symbols located before and after the segment synchronization component. FIG. 2(a) is a graph showing an example of the signal strength of an in-phase component, and an example of the signal strength of a quadrature component occurring due to effects of a VSB filter in the transmitter, when 1 is transmitted as the in-phase component at time 0. FIG. 2(b) is a graph showing an example of the signal strength of an in-phase component, and an example of the signal strength of a quadrature component occurring due to effects of the VSB filter in the transmitter, when −1 is transmitted as the in-phase component at time 1. In FIGS. 2(a) and 2(b), time is expressed in units of symbol intervals T.

As shown in FIG. 2(a), when the in-phase component is 1, the quadrature component at that time is 0, however, the quadrature component one symbol before is −0.7, and the quadrature component one symbol after is 0.7. Also, as shown in FIG. 2(b), when the in-phase component is −1, the quadrature component at that time is 0, however, the quadrature component one symbol before is 0.7, and the quadrature component one symbol after is −0.7. This means that when a phase error is detected from the segment synchronization component, the detection is greatly affected by the symbols located before and after the segment synchronization component.

Furthermore, in the technique in Patent Document 1, when a phase error varies greatly, a phase error correction section cannot follow the phase error accurately.

It is therefore an object of the present invention to provide a VSB demodulator that properly demodulates a received VSB modulated signal even when phase error variation occurs in the received VSB modulated signal.

### Means for Solving the Problem

A VSB (Vestigial Sideband) demodulator according to an example embodiment of the present invention demodulates a VSB modulated signal including a plurality of fields each having a plurality of segments, the plurality of fields each having as one of the plurality of segments a field synchronization component containing a predetermined PN (Pseudo Noise) sequence, the plurality of segments each having a segment synchronization component having predetermined four symbols. The VSB demodulator includes: a channel estimation section configured to perform a convolution operation between the VSB modulated signal and the predetermined PN sequence, and generate a timing signal synchronous with the segment synchronization components of the VSB modulated signal according to results of the operation; a phase variation detection section configured to detect a phase error in the VSB modulated signal in accordance with timing indicated by the timing signal, and output a detection signal corresponding to variation in the detected phase error; and a waveform equalization section, including a filter, configured to update a coefficient of the filter and perform waveform equalization on the VSB modulated signal. The waveform equalization section increases a coefficient update gain for the filter when the detection signal indicates that the variation in the phase error is larger than a predetermined value.

According to the example embodiment, the coefficient update gain for the filter is increased when the phase error variation is larger than a predetermined value. It is thus possible for the VSB demodulator to perform demodulation more properly even when phase error variation is large.

Also, a television receiver according to an example embodiment of the present invention includes: a tuner section configured to receive a VSB modulated high-frequency signal, tune the received high-frequency signal, convert the tuned signal into a baseband signal, and output a resultant VSB modulated signal, the high-frequency signal having been VSB-modulated in such a manner that the high-frequency signal includes a plurality of fields each having a plurality of segments, and that the plurality of fields each include as one of the plurality of segments a field synchronization component containing a predetermined PN sequence, and that the plurality of segments each have a segment synchronization component having predetermined four symbols; the VSB demodulator configured to demodulate the VSB modulated signal output from the tuner section; and a back end section configured to decode results of demodulation performed by the VSB demodulator, and output a resultant video/audio signal.

### Effects of the Invention

According to the example embodiments of the present invention, the coefficient update gain in the waveform equalization section is adaptively controlled on the basis of results of detection of phase error variation, thereby realizing high demodulation performance even in the case of a signal having large phase error variation. Furthermore, since a phase error is detected in limited symbols, the phase error and variation therein are detected with high accuracy, and no complicated processing is performed, allowing the circuit area to be reduced relatively.

### BRIEF DESCRIPTION OF DRAWINGS

FIG. 1 illustrates the configuration of a data frame defined by the Advanced Television Systems Committee (ATSC) adopted in North America, etc.

FIG. 2(a) is a graph showing an example of the signal strength of an in-phase component, and an example of the signal strength of a quadrature component occurring due to effects of a VSB filter in a transmitter, when 1 is transmitted as the in-phase component at time 0. FIG. 2(b) is a graph showing an example of the signal strength of an in-phase component, and an example of the signal strength of a quadrature component occurring due to effects of the VSB filter in the transmitter, when −1 is transmitted as the in-phase component at time 1.

FIG. 3 is a block diagram illustrating the configuration of a VSB demodulator according to an embodiment of the present invention.

FIG. 4 is a block diagram illustrating an example of the configuration of a phase variation detection section shown in FIG. 3.

FIG. 5 is a timing chart showing examples of timing signals S1 and S2, of an in-phase component I, and of a quadrature component Q shown in FIG. 3.

FIG. 6(a) illustrates in-phase components and quadrature components of the second and third symbols in a segment synchronization component, detected when there is no phase error. FIG. 6(b) illustrates in-phase components detected when there is a phase error in the positive direction. FIG. 6(c) illustrates in-phase components detected when there is a phase error in the negative direction.

FIG. 7 is a block diagram illustrating an example of the configuration of a waveform equalization section shown in FIG. 3.

FIG. 8 is a block diagram illustrating the configuration of a modified example of the VSB demodulator shown in FIG. 3.

FIG. 9 is a block diagram illustrating an example of the configuration of a waveform equalization section shown in FIG. 8.

FIG. 10 is a block diagram illustrating the configuration of a television receiver including the VSB demodulator shown in FIG. 3.

### EXPLANATION OF THE REFERENCE CHARACTERS

2, 202 Channel estimation section
30, 230A, 230B Phase variation detection section
40, 240 Waveform equalization section
100, 200 VSB demodulator
110 Television receiver
111 Tuner section
113 Back end section

### BEST MODE FOR CARRYING OUT THE INVENTION

Hereinafter, embodiments of the present invention will be described with reference to the accompanying drawings.

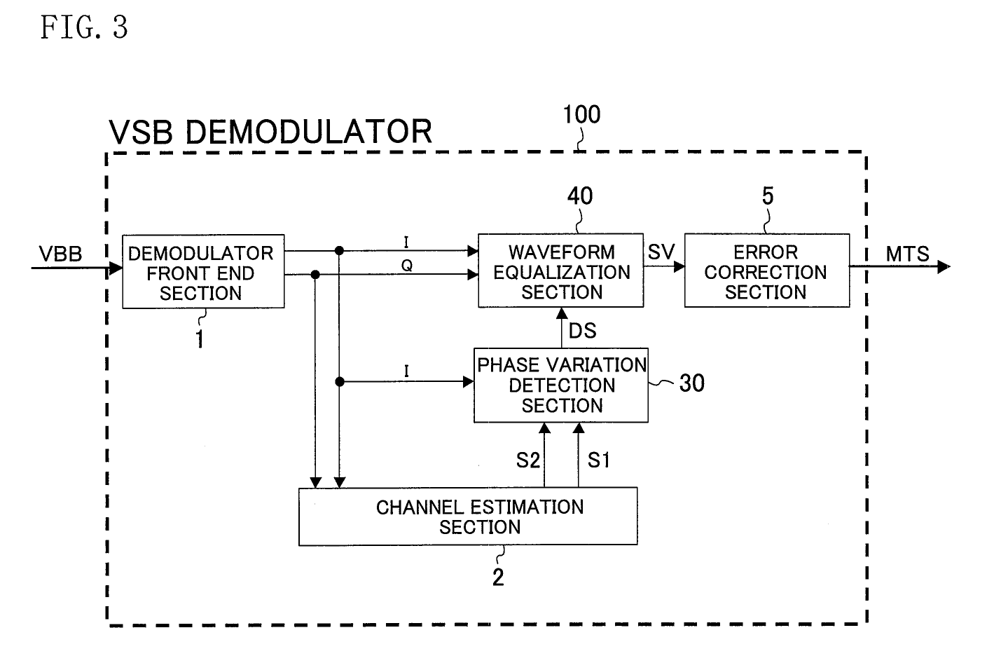

FIG. 3 is a block diagram illustrating the configuration of a VSB demodulator according to an embodiment of the present invention. The VSB demodulator shown in FIG. 3 includes a demodulator front end section 1, a channel estimation section 2, a phase variation detection section 30, a waveform equalization section 40, and an error correction section 5.

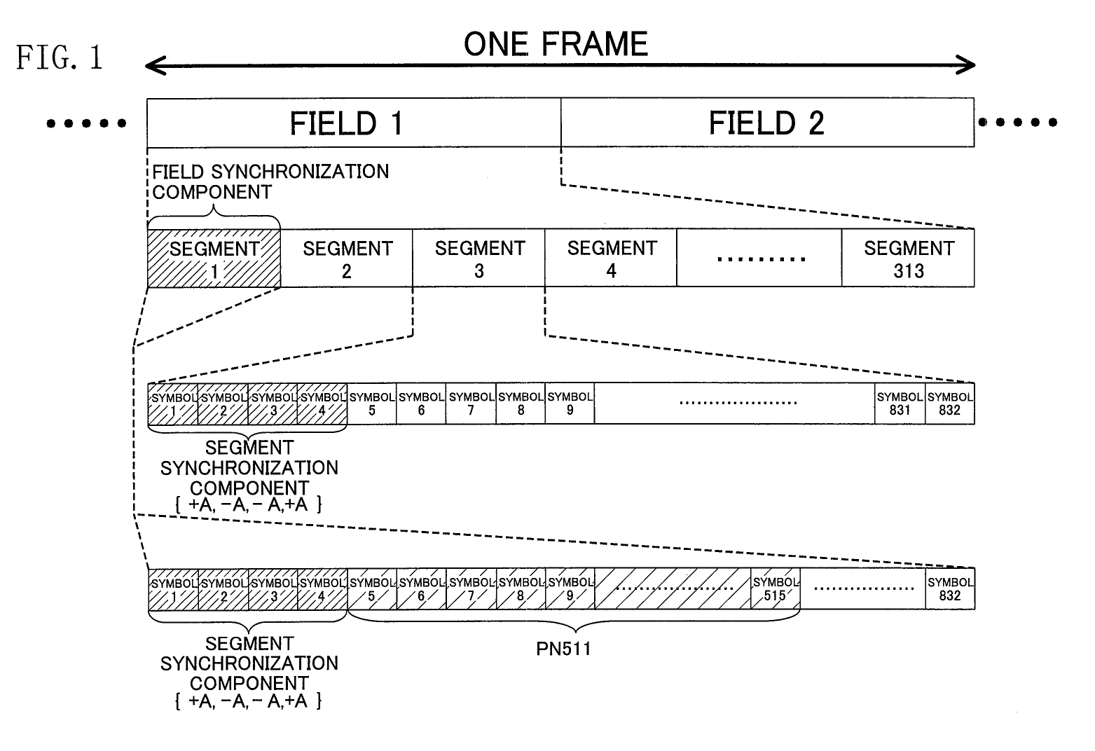

The demodulator front end section 1 receives a VSB modulated received signal VBB from a tuner section, etc, performs AD conversion processing, carrier recovery processing, and clock recovery processing on this signal VBB, and outputs the result as a VSB modulated signal, which is a complex signal. This VSB modulated signal is composed of an in-phase component I and a quadrature component Q, and transmits data such as shown in FIG. 1.

The VSB modulated signal defined by ATSC as shown in FIG. 1 consecutively contains data frames such as shown in FIG. 1. Each data frame consists of two data fields, each containing 313 data segments. Each data segment includes 832 symbols. Data fields and data segments will be hereinafter referred to as “fields” and “segments”, respectively.

The first segment of the 313 segments forming each field is defined as a field synchronization component which contains a pseudo-random sequence PN511 in a predetermined location. The first four symbols of the 832 symbols forming each segment are defined as a segment synchronization component (the first symbol is +A, the second symbol is −A, the third symbol is −A, and the fourth symbol is +A (where A is a natural number)).

The channel estimation section 2 performs convolutions between (i) each of the in-phase component I and the quadrature component Q, and (ii) the pseudo-random sequence PN511, and adds the respective operation results together to obtain a delay profile. The pseudo-random sequence PN511 is consecutive 511 symbols having a specific sequence, and is defined by ATSC. The channel estimation section 2 regards the largest value in the obtained delay profile as corresponding to a main signal (a desired signal) of the VSB modulated signal, generates start time for a field that is synchronous with this main signal, and also generates timing signals S1 and S2 that are synchronous with the segment synchronization components.

The timing signal S1 has a value of 1 at the time of the second symbol of the first to fourth symbols serving as each of the segment synchronization components of the main signal, and has a value of 0 at the other times. The timing signal S2 has a value of 1 at the time of the third symbol of each of the segment synchronization components, and has a value of 0 at the other times.

The phase variation detection section 30 detects phase error variation according to the in-phase component I and the timing signals S1 and S2. When there is phase error variation, the phase variation detection section 30 outputs 1 as a detection signal DS. When there is no phase error variation, the phase variation detection section 30 outputs 0 as the detection signal DS. According to the in-phase component I, the quadrature component Q, and the detection signal DS, the waveform equalization section 40 performs waveform equalization on the VSB modulated signal output from the demodulator front end section 1 so as to remove a delayed signal, phase error and low-speed phase error variation from the VSB modulated signal, and outputs the resultant symbol value SV. The error correction section 5 discriminates the symbol value SV, corrects an error in the symbol value SV, and outputs the result as a stream MTS, which is an MPEG2-TS (Moving Picture Experts Group 2-Transport Stream).

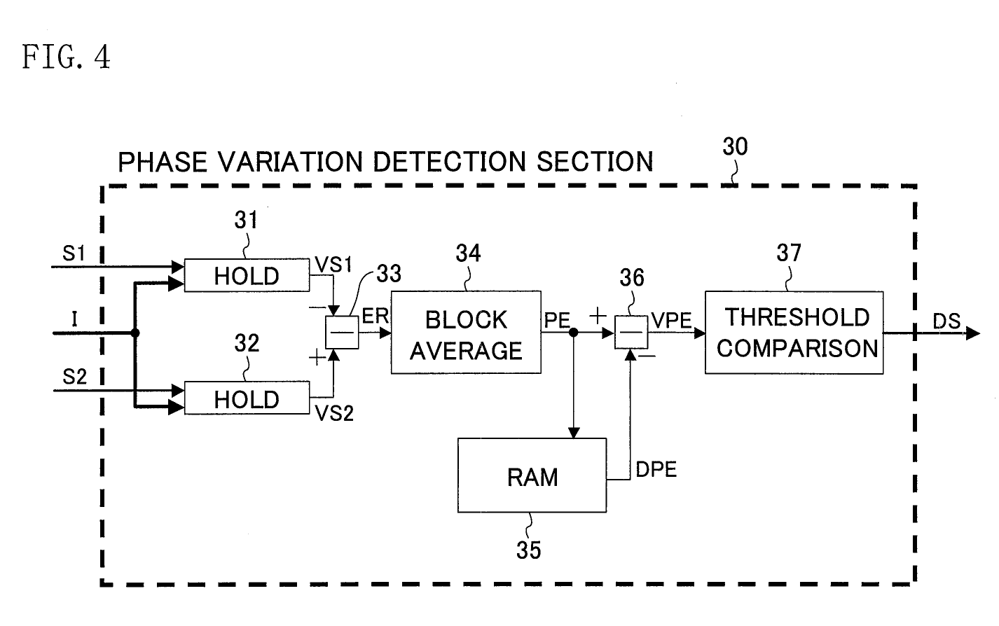

FIG. 4 is a block diagram illustrating an example of the configuration of the phase variation detection section 30 shown in FIG. 3. The phase variation detection section 30 includes hold sections 31 and 32, subtractors 33 and 36, a block average section 34, a RAM (Random Access Memory) 35, and a threshold comparison section 37.

The hold section 31 retains the value of the in-phase component I obtained when the timing signal S1 has a value of 1, and outputs the retained value as a value VS1. The hold section 32 retains the value of the in-phase component I obtained when the timing signal S2 has a value of 1, and outputs the retained value as a value VS2. The subtractor 33 subtracts the value VS1 from the value VS2 to output the subtraction result as a piece of error information ER. The block average section 34 calculates the average of five pieces of error information ER, each of which has been calculated for each segment, and outputs the result as a phase error PE for each set of five segments.

The RAM 35 stores the phase error PE, delays the stored phase error PE by a time period equal to 100 segments, and outputs the delayed error PE as a delayed phase error DPE. The subtractor 36 subtracts the delayed phase error DPE from the phase error PE, and outputs the absolute value of the subtraction result as a phase variation amount VPE. The threshold comparison section 37 compares the phase variation amount VPE with a predetermined threshold value. When the phase variation amount VPE is larger than the threshold value, the threshold comparison section 37 outputs 1 as the detection signal DS. When the phase variation amount VPE is equal to or lower than the threshold value, the threshold comparison section 37 outputs 0 as the detection signal DS.

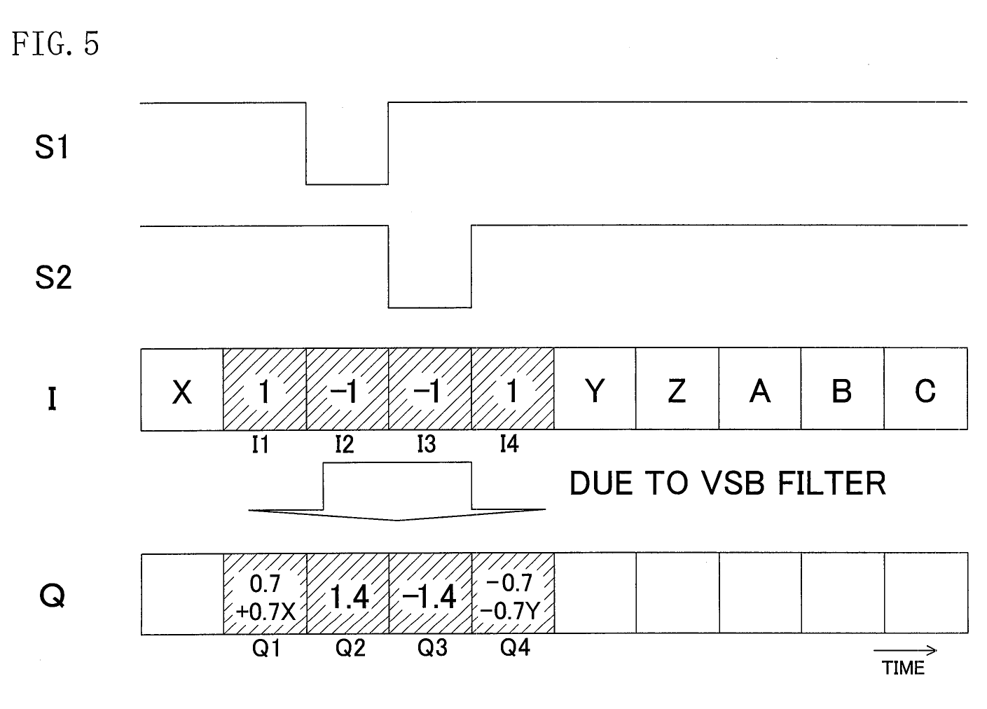

FIG. 5 is a timing chart showing examples of the timing signals S1 and S2, in-phase component I, and quadrature component Q shown in FIG. 3. It is assumed herein that the input VSB modulated signal is an ideal signal that contains no delayed signal, no noise, and no phase error, and that the absolute value A of the in-phase component is 1, for example. In this case, the respective in-phase components I1, I2, I3, and I4 of the first to fourth symbols in the segment synchronization component are defined as follows:

I1=1, I2=−1, I3=−1, and I4=1

For example, the timing signal S1 goes to the “L” level only at the time of the second symbol, and the timing signal S2 goes to the “L” level only at the time of the third symbol.

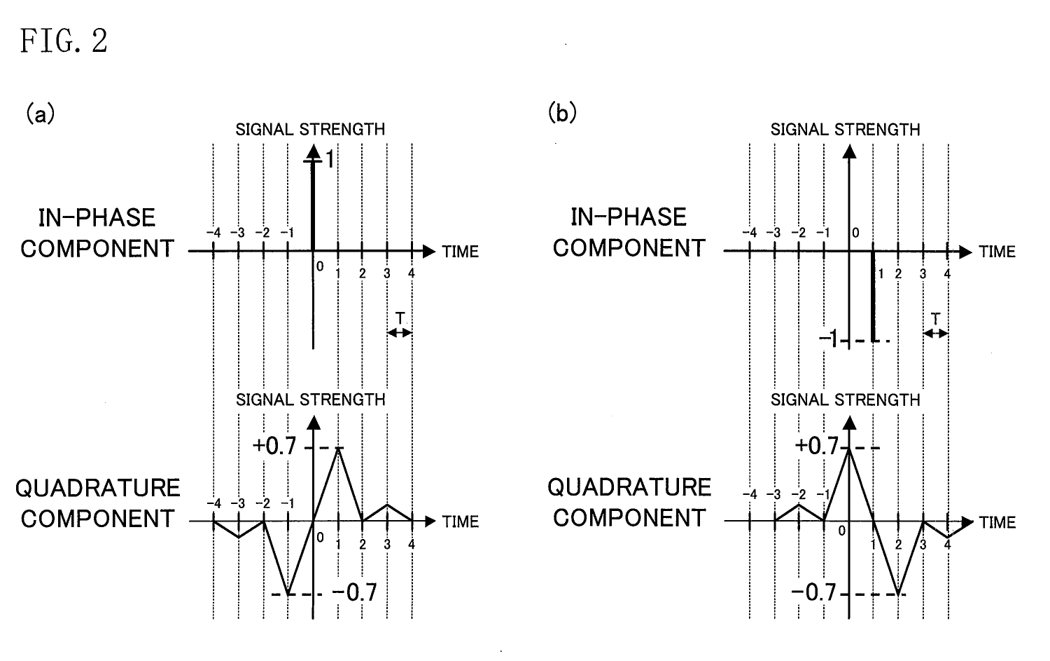

As described with reference to FIG. 2, due to the effects of the VSB filter in the transmitter, the quadrature component Q of a symbol is affected by the in-phase components I of the symbols located before and after that symbol. Using the relation between the in-phase component and the quadrature component shown in FIGS. 2(a) and 2(b), the respective quadrature components Q1, Q2, Q3, and Q4 of the first to forth symbols in the segment synchronization component are expressed as follows:

Q1=0.7+0.7X

Q2=1.4

Q3=−1.4

Q4=−(0.7+0.7Y)

where X represents the value of the in-phase component I one symbol before the four symbols serving as the segment synchronization component, and Y is the value of the in-phase component I one symbol after the four symbols serving as the segment synchronization component. That is, it is found that the quadrature components Q1 and Q4 of the first and fourth symbols in the segment synchronization component are greatly affected by the indefinite values (X, Y) positioned before and after the segment synchronization component, while the quadrature components Q2 and Q3 of the second and third symbols in the segment synchronization component are not affected by the indefinite values.

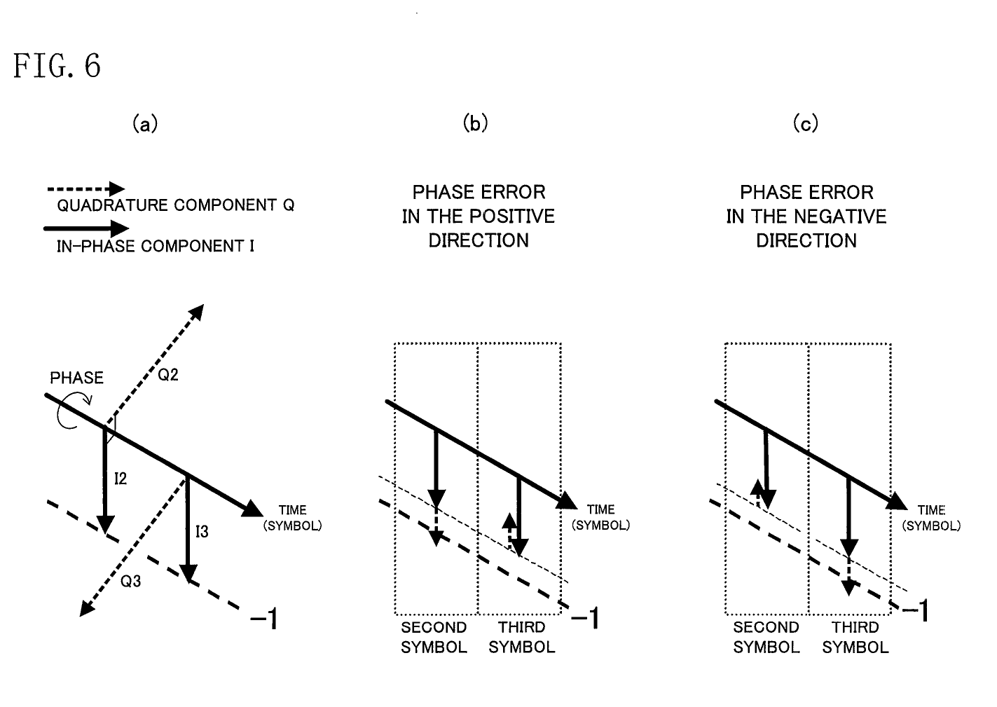

FIG. 6(a) illustrates in-phase components and quadrature components of the second and third symbols in the segment synchronization component, detected when there is no phase error. FIG. 6(b) illustrates in-phase components detected when there is a phase error in the positive direction. FIG. 6(c) illustrates in-phase components detected when there is a phase error in the negative direction.

The subtractor 33 shown in FIG. 4 obtains a difference between the in-phase components of the second and third symbols in the segment synchronization component as the error information ER. As shown in FIGS. 6(b) and 6(c), the in-phase component of the second symbol corresponds to the sum of two vectors that are perpendicular components resulting from rotation of the in-phase component I2 and quadrature component Q2 around the time axis by the actual phase error. The in-phase component of the third symbol corresponds to the sum of two vectors that are perpendicular components resulting from rotation of the in-phase component I3 the quadrature component Q3 in the same manner.

As described with reference to FIG. 5, the absolute values of the quadrature components Q2 and Q3 are larger than the absolute values of the in-phase components I2 and I3, respectively. Because of large quadrature components, when a phase error in the positive or negative direction is present as shown in FIGS. 6(b) and 6(c), a value having a large absolute value is obtained as the phase error, thereby enabling the highly accurate phase error detection.

In this way, since the phase variation detection section 30 shown in FIG. 4 uses the in-phase components of the second and third symbols in the segment synchronization component, a phase error is detected highly accurately with little effect from the symbols located before and after the segment synchronization component.

It should be noted that the segment synchronization component of a segment (e.g., the first segment in FIG. 1) serving as a field synchronization component does not need to be used, but the segment synchronization component of other segments may be used in detecting a phase error. In that case, it becomes possible to avoid effects of interference of the pseudo-random sequence PN511 with the segment synchronization component, thereby enabling phase error detection with higher accuracy.

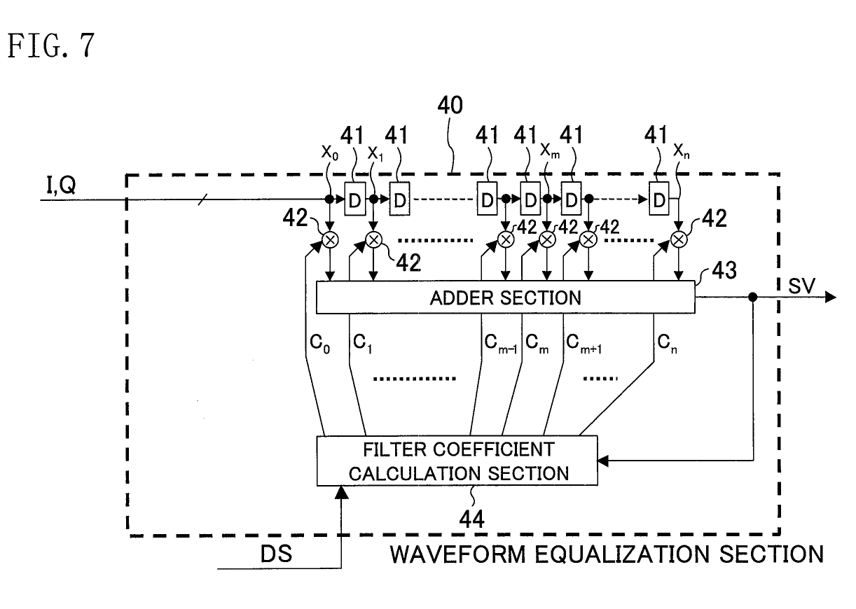

FIG. 7 is a block diagram illustrating an example of the configuration of the waveform equalization section 40 shown in FIG. 3. The waveform equalization section 40 includes n delay devices 41, n+1 multipliers 42, an adder section 43, and a filter coefficient calculation section 44. The n delay devices 41, the n+1 multipliers 42, and the adder section 43 form a filter.

The leftmost delay device 41 in FIG. 7 delays an input in-phase component I and an input quadrature component Q (which will be hereinafter referred to together as a “signal X0”) by one symbol, and outputs the delayed signal to the delay device 41 in the next stage as a signal X1. The other delay devices 41 likewise delay input signals by one symbol, and output the delayed signals as signals X2, X3, . . . , Xm, . . . , and Xn (where n and m are integers equal to or greater than 0). Each of the n+1 multipliers 42 multiplies a corresponding signal Xm by a corresponding filter coefficient Cm (where 0≦m≦n), and outputs the multiplication result to the adder section 43. The adder section 43 adds the multiplication results of all of the multipliers 42 together, and outputs the resultant symbol value SV.

Each time the delay devices 41 delay signals by one symbol, the filter coefficient calculation section 44 updates each filter coefficient Cm. At this time, for each filter coefficient Cm, the filter coefficient calculation section 44 multiplies a difference between the symbol value SV and an expected value by a coefficient update gain for that filter coefficient Cm by a corresponding signal Xm, accumulates the multiplication result, and outputs the resultant accumulated value as a new filter coefficient Cm. Now, it is assumed that the filter coefficient of a tap corresponding to the main signal is Ca (where a is an integer which satisfies 0≦a≦n). When the detection signal DS has a value of 1, the filter coefficient calculation section 44 increases (e.g., quadruples) only the coefficient update gain for the filter coefficient Ca as compared to when the detection signal DS has a value of 0.

In this manner, the waveform equalization section 40 shown in FIG. 7 adaptively controls the coefficient update gain according to phase error variation, thereby enabling highly accurate demodulation even with the presence of the phase error variation.

The phase variation detection section 30 has been described above by providing the example number of pieces of the error information ER averaged, and the example time by which the phase error PE is delayed. However, a different number of pieces and a different time period may be employed.

Furthermore, a plurality of time periods (for example, a time period equal to 100 segments and a time period equal to 20 segments) may be set as the time by which the phase error PE is delayed, so that the phase variation detection section 30 detects the presence or absence of phase error variation corresponding to the set time periods. In this case, the detection signal DS may indicate the result of comparison with a threshold value in correspondence to the set time periods so that the coefficient update gain is controlled in more detail according to the detection signal DS.

Also, in the foregoing description, the filter coefficient calculation section 44 increases the coefficient update gain only for a specific filter coefficient. However, the filter coefficient calculation section 44 may be configured to increase the coefficient update gains for a plurality of filter coefficients in the vicinity of the specific filter coefficient as well, or may be configured to increase the coefficient update gains for all of the filter coefficients.

Moreover, as the waveform equalization section 40, the simplest example configuration has been described, however, the configuration of the waveform equalization section 40 is not limited to this.

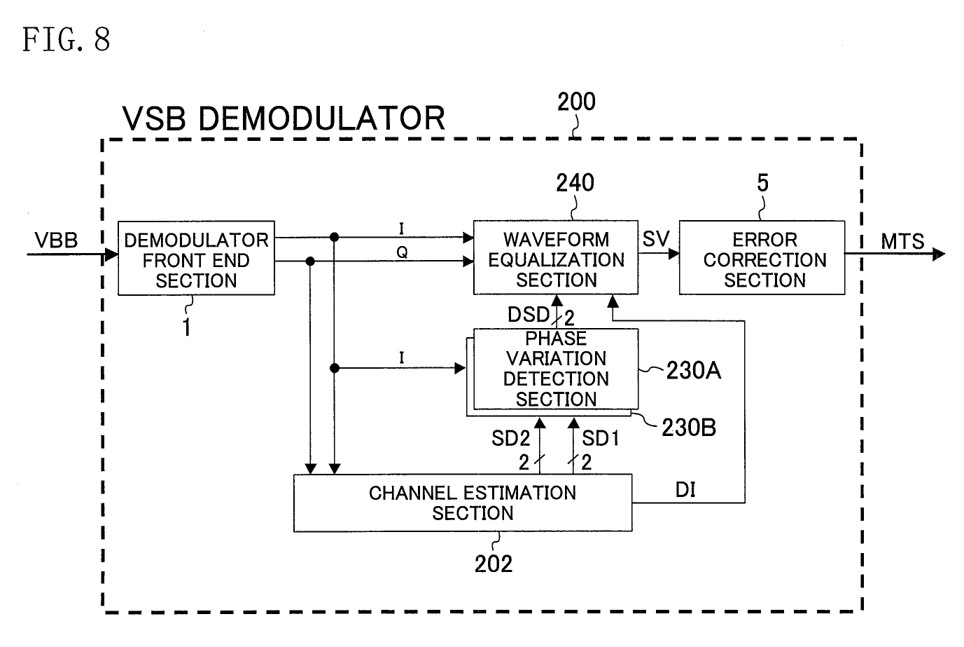

FIG. 8 is a block diagram illustrating the configuration of a modified example of the VSB demodulator shown in FIG. 3. The VSB demodulator 200 shown in FIG. 8 includes phase variation detection sections 230A and 230B in place of the phase variation detection section 30, and includes a channel estimation section 202 and a waveform equalization section 240 instead of the channel estimation section 2 and the waveform equalization section 40. In the other respects, the VSB demodulator 200 is configured in the same manner as the VSB demodulator 100 shown in FIG. 3.

The channel estimation section 202, like the channel estimation section 2 shown in FIG. 3, obtains a delay profile. The channel estimation section 202 regards the largest value in the obtained delay profile as corresponding to the main signal of the VSB modulated signal, and the second largest local maximum value therein as corresponding to the delayed signal of the VSB modulated signal. The channel estimation section 202 generates start time for a field that is synchronous with these main and delayed signals, and also generates timing signals SD1 and SD2.

The higher order bit in the timing signal SD1 has a value of 1 at the time of the second symbol of each of the segment synchronization components of the main signal, and has a value of 0 at the other times. The higher order bit in the timing signal SD2 has a value of 1 at the time of the third symbol of each of the segment synchronization components of the main signal, and has a value of 0 at the other times. The lower order bit in the timing signal SD1 has a value of 1 at the time of the second symbol of each of the segment synchronization components of the delayed signal, and has a value of 0 at the other times. The lower order bit in the timing signal SD2 has a value of 1 at the time of the third symbol of each of the segment synchronization components of the delayed signal, and has a value of 0 at the other times. The channel estimation section 202 outputs a delay difference between the main signal and the delayed signal as delay information DI.

The phase variation detection section 230A is configured similar to the phase variation detection section 30 shown in FIG. 4, except that the phase variation detection section 230A receives the higher order bit in each of the timing signals SD1 and SD2 instead of the timing signals S1 and S2. The phase variation detection section 230B is configured similar to the phase variation detection section 30 shown in FIG. 4, except that the phase variation detection section 230B receives the lower order bit in each of the timing signals SD1 and SD2 instead of the timing signals S1 and S2. The phase variation detection sections 230A and 230B output results of comparison with a threshold value as the higher order bit and lower order bit of a detection signal DSD, respectively.

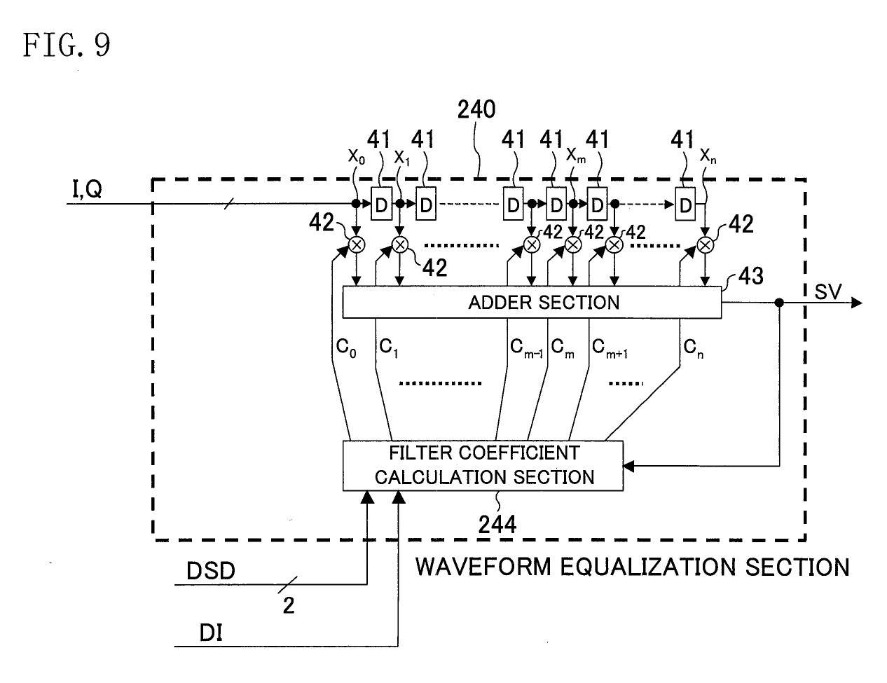

FIG. 9 is a block diagram illustrating an example of the configuration of the waveform equalization section 240 shown in FIG. 8. The waveform equalization section 240 is configured similar to the waveform equalization section 40 shown in FIG. 7, except that the waveform equalization section 240 includes a filter coefficient calculation section 244 in place of the filter coefficient calculation section 44. Now assume that the delay information DI showing a delay difference between the main signal and the delayed signal indicates b−a, and that the filter coefficient of a tap corresponding to the main signal is Ca (where a and b are integers which satisfy 0≦a≦b≦n). In this case, the filter coefficient of a tap corresponding to the delayed signal is Cb.

When the higher order bit and lower order bit in the detection signal DSD are 0 and 1, respectively (i.e., when there is phase error variation only in the delayed signal), the filter coefficient calculation section 244 increases (e.g., quadruples) only the coefficient update gain for the filter coefficient Cb. When the higher order bit and lower order bit in the detection signal DSD are 1 and 0, respectively (i.e., when there is phase error variation only in the main signal), the filter coefficient calculation section 244 increases (e.g., quadruples) only the coefficient update gain for the filter coefficient Ca. In the other respects, the filter coefficient calculation section 244 is the same as the filter coefficient calculation section 44 shown in FIG. 7.

In this way, the VSB demodulator shown in FIG. 8 enables detection of phase error variation in the delayed signal as well. In particular, even when there is phase error variation only either in the main signal or in the delayed signal, highly accurate demodulation is possible.

In the foregoing description the filter coefficient calculation section 244 increases the coefficient update gain only for a specific filter coefficient. However, the filter coefficient calculation section 244 may be configured to increase the coefficient update gains for a plurality of filter coefficients in the vicinity of the specific filter coefficient as well.

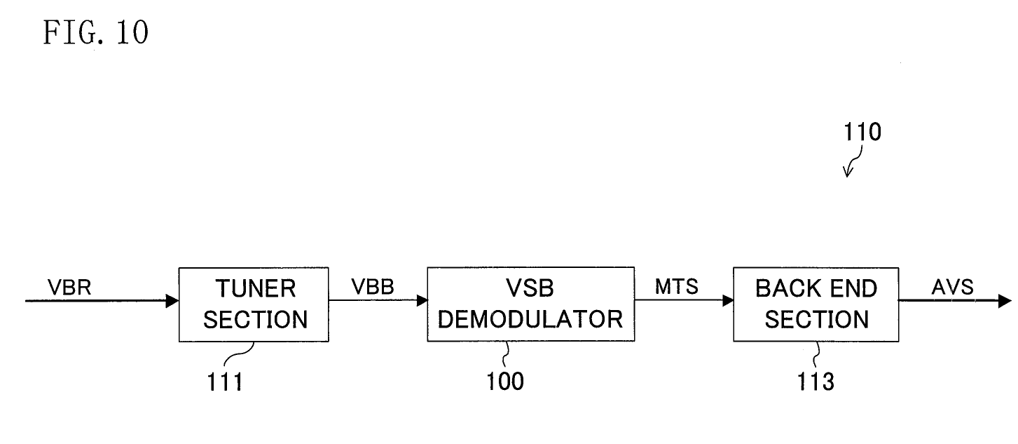

FIG. 10 is a block diagram illustrating the configuration of a television receiver 110 including the VSB demodulator 100 shown in FIG. 3. The television receiver 110 includes a tuner section 111, the VSB demodulator 100 shown in FIG. 3, and a back end section 113.

The tuner section 111 receives a VSB modulated high-frequency signal VBR from an antenna, etc., tunes the high-frequency signal VBR, converts the tuned signal into a baseband signal, and outputs the resultant VSB modulated reception signal VBB. The VSB demodulator 100 demodulates the reception signal VBB as described above, and outputs the resultant stream MTS as the demodulation result. The back end section 113 decodes the stream MTS and outputs the resultant video/audio signal AVS.

Since the VSB demodulator 100 is capable of highly accurate demodulation even with the presence of phase error variation, the television receiver 110 is able to output a clear video/audio signal even in a place (for example, a high traffic area) where reception environment varies.

In the television receiver shown in FIG. 10, the VSB demodulator 200 shown in FIG. 8 may be used in place of the VSB demodulator 100.

### INDUSTRIAL APPLICABILITY

As described above, according to the example embodiments of the present invention, highly accurate demodulation is possible even when there is phase error variation. The present invention is thus applicable to demodulators, television receivers using demodulators, etc.

1. A VSB (Vestigial Sideband) demodulator configured to demodulate a VSB modulated signal including a plurality of fields each having a plurality of segments, the plurality of fields each having as one of the plurality of segments a field synchronization component containing a predetermined PN (Pseudo Noise) sequence, the plurality of segments each having a segment synchronization component having predetermined four symbols, the VSB demodulator comprising:
a channel estimation section configured to perform a convolution operation between the VSB modulated signal and the predetermined PN sequence, and generate a timing signal synchronous with the segment synchronization components of the VSB modulated signal according to results of the operation;
a phase variation detection section configured to detect a phase error in the VSB modulated signal in accordance with timing indicated by the timing signal, and output a detection signal corresponding to variation in the detected phase error; and
a waveform equalization section, including a filter, configured to update a coefficient of the filter and perform waveform equalization on the VSB modulated signal,
wherein the waveform equalization section increases a coefficient update gain for the filter when the detection signal indicates that the variation in the phase error is larger than a predetermined value.

2. The VSB demodulator of claim 1, wherein the phase variation detection section detects as the phase error a difference between in-phase components of second and third symbols of the symbols included in the segment synchronization component.

3. The VSB demodulator of claim 1, wherein the phase variation detection section detects the phase error by using the segment synchronization component of a segment other than the segment that is the field synchronization component.

4. The VSB demodulator of claim 1, wherein the channel estimation section further generates as the timing signal a signal which is synchronous with the segment synchronization components or a delayed signal of the VSB modulated signal.

5. A television receiver comprising:
a tuner section configured to receive a VSB modulated high-frequency signal, tune the received high-frequency signal, convert the tuned signal into a baseband signal, and output a resultant VSB modulated signal, the high-frequency signal having been VSB-modulated in such a manner that the high-frequency signal includes a plurality of fields each having a plurality of segments, and that the plurality of fields each include as one of the plurality of segments a field synchronization component containing a predetermined PN sequence, and that the plurality of segments each have a segment synchronization component having predetermined four symbols;
the VSB demodulator of claim 1 configured to demodulate the VSB modulated signal output from the tuner section; and
a back end section configured to decode results of demodulation performed by the VSB demodulator, and output a resultant video/audio signal.
